(19) United States
(12) Patent Application Publication
(10) Pub. No.: US 2025/0233052 A1
(43) Pub. Date: Jul. 17, 2025

(54) METHOD FOR PRODUCING A COOLING DEVICE

(71) Applicant: Miba Sinter Austria GmbH, Laakirchen (AT)

(72) Inventors: Daniel RIEMER, Altmünster (AT); Markus LUDWIG-ETZLSTORFER, Marchtrenk (AT); Klaus RICHTER, Vorchdorf (AT); Manuel POHN, Zell am Pettenfirst (AT)

(73) Assignee: Miba Sinter Austria GmbH, Laakirchen (AT)

(21) Appl. No.: 19/014,486

(22) Filed: Jan. 9, 2025

(30) Foreign Application Priority Data
Jan. 16, 2024 (AT) A50020/2024

(51) Int. Cl. H01L 23/46; B22F 5/00; H01L 21/48

(52) U.S. Cl. CPC H01L 23/46; H01L 21/4882; B22F 5/00; B22F 2005/005; B22F 2301/052

(57) ABSTRACT

A method for producing a cooling device with a bottom element and a cover element connected thereto, wherein a cooling structure with cooling elements is arranged between the bottom element and the cover element, includes the steps of providing a material and configuring a cooling structure from the material, wherein a sintering powder is used as the material, from which at least one green compact is produced by pressing, the green compact is sintered to form a preform, and the cooling structure in the form of cooling elements is produced from the preform by forming, for which purpose a part of the preform is pressed through a mold, and after arrangement of the cooling structure between the bottom element and the cover element, the bottom element is joined to the cover element in a substance bonding.

### CROSS REFERENCE TO RELATED APPLICATIONS

Applicant claims priority under 35 U.S.C. § 119 of Austrian Application No. A50020/2024 filed Jan. 16, 2024, the disclosure of which is incorporated by reference.

### BACKGROUND OF THE INVENTION

### 1. Field of the Invention

The invention relates to a method for producing a cooling device with a bottom element and a cover element connected thereto, wherein a cooling structure with cooling elements is arranged between the bottom element and the cover element, comprising the steps of providing a material and configuring a cooling structure from the material.

The invention also relates to a cooling device comprising a bottom element and a cover element connected thereto, wherein a cooling structure with cooling elements is arranged between the bottom element and the cover element.

### 2. Description of the Related Art

So-called power electronics components, such as power semiconductors, are well known from the state of the art. Such components are frequently used, for example in motor vehicles. It is also known that these components generate large amounts of heat during operation, which often needs to be dissipated using a cooling medium. A wide variety of coolers are known in the prior art for this purpose, including so-called pin fin heat sinks, which are surrounded by a cooling medium and thus transfer the heat from the pins to the cooling medium. DE 10 2019 108 106 A1 describes for example a cooler for a power semiconductor in an inverter, wherein the cooler is configured in two parts and comprises a base plate as a first part, which can be connected to the power semiconductor in a thermally conductive manner; a heat sink as a second part, which is arranged on the base plate, wherein the heat sink has at least one wave-shaped recess, which is formed continuously from a side of the heat sink facing away from the base plate to a side facing the heat sink; wherein the first and second parts are connected to one another and are coated with a layer, which protects both parts from electrochemical reduction.

DE 10 2018 216 859 A1 discloses a device for cooling components, including a first and a second base body; cylindrical and/or conical first cooling fins which are configured in the first base body and around which a coolant can flow, and cylindrical and/or conical second cooling fins which are configured in the second base body and around which the coolant can flow, the second base body being joined to the first base body in such a way that the second cooling fins come to lie between the first cooling fins without touching the first base body.

### SUMMARY OF THE INVENTION

The present invention is based on the object of simplifying the production of a cooling device and providing a corresponding cooling device for components with an enhanced cooling performance.

The object of the invention is solved by the method mentioned at the beginning, according to which it is provided that a sintering powder is used as the material, from which at least one green compact is produced by pressing, that the green compact is sintered to form a preform, and that the cooling structure in the form of cooling elements is produced from the preform by forming, for which purpose a part of the preform is pressed through a mold, and that, after the cooling structure has been arranged between the bottom element and the cover element, the bottom element is joined to the cover element in a substance bonding.

Furthermore, the object of the invention is solved with the cooling device mentioned at the beginning, in which the cooling structure is made of a formed sinter material and the bottom element is joined to the cover element in a substance bonding.

The advantage here is that no waste material is produced for the cooling elements produced by forming, as is the case with machining, for example. In addition, several or all of the cooling elements of the cooling device can be produced at the same time, which may lead to a corresponding increase in productivity. The advantage for forming is that the preform, although it already has a corresponding strength due to sintering, is easier to form due to the pores compared to a solid material. When the preform is formed to the cooling elements, stresses can be generated in them that have a positive effect on their mechanical behavior during use of the cooling device. The substance bonding between the bottom element and the cover element means that a fluid-tight cooling device may be provided for the cooling structure, apart from an inlet and an outlet for a cooling fluid, so that it may be used in a wide variety of applications without any problems and without any further special precautions having to be taken (with the exception of integrating the cooling device into a cooling circuit). The enclosed configuration of the cooling structure makes it particularly easy to use in electronics applications.

According to an embodiment variant of the invention, it may be provided that the bottom element is produced from at least one preform and/or the cover element is produced from at least one preform. The production of the bottom element and/or the cover element in a sinter process makes it easier to adapt them to the cooling structure.

According to a further embodiment variant of the invention, it is advantageous if cooling elements of the cooling structure are configured in one piece with the bottom element and/or cooling elements of the cooling structure are configured in one piece with the cover element. It is therefore possible to produce both cooling elements and the bottom element or cover element in a single method step, which makes their production more economical. The one-piece configuration also means that no further measures are required to fix the position of the cooling structure.

According to a further embodiment variant of the invention, it may be provided that the substance bonding is configured outside the area of the cooling structure. This makes it possible to avoid influencing the cooling structure, e.g. thermal influencing, by configuring the substance bonding. This also makes it possible to configure the cooling structure regardless of the requirements for the configuration of the substance bonding.

According to a further embodiment variant of the invention, it may be provided that a joining gap is formed in the bottom element or in the cover element to configure the substance bonding. This makes it possible to define an area in which the substance bonding is configured so that interaction between the cooling structure and the substance bonding can be more easily avoided during the production of the connection. This also makes it easier to automate the “substance bonding” method step, especially if a filler material is used for the substance bonding, as the joining gap can be used to avoid or prevent the filler material from running when configuring the substance bonding.

According to a further embodiment variant of the invention, it may be provided that the substance bonding is configured as a soldered connection in order to keep the temperature load on the cooling structure low during the configuration of the substance bonding and to minimize or avoid a reduction in stress in the cooling elements.

According to an embodiment variant, the soldered connection may be produced by inductive soldering or sinter soldering. Inductive soldering allows the heat input into the bottom element and the cover element to be limited to a very narrow range when configuring the substance bonding. On the other hand, sinter soldering may simplify the method by producing the substance bonding when passing through a sintering furnace. A more uniform property profile may also be formed over the entire cooling device.

For greater stability of the cooling device, according to an embodiment variant of the invention it may be provided that at least some of the cooling elements are connected to both the bottom element and the cover element. As a result, it is also possible to reduce the thickness of the bottom element or the cover element, which reduces the thermal resistance and thus increases the cooling capacity of the cooling device.

In order to simplify the connection of the cooling element to the cover element or the bottom element, according to an embodiment variant of the invention, joining recesses may be formed in the heads of the cooling elements, which are connected both to the bottom element and to the cover element, to receive a filler material.

To improve corrosion resistance, a coating may be applied to the cooling structure in accordance with a further embodiment variant of the invention.

According to a further embodiment variant of the invention, the coating may be applied before or after the bottom element is joined to the cover element in a substance bonding. By applying the coating before the substance bonding is created, the coating process itself can be simplified, particularly in areas that are difficult to access. By applying the coating after the substance bonding has been created, the placement of the substance bonding on the bottom element and the cover element can be simplified, in particular by configuring them closer to the cooling structure, as it is possible to avoid covering these areas to prevent the coating from being deposited in these areas.

### BRIEF DESCRIPTION OF THE DRAWINGS

Other objects and features of the invention will become apparent from the following detailed description considered in connection with the accompanying drawings. It is to be understood, however, that the drawings are designed as an illustration only and not as a definition of the limits of the invention.

In the drawings,

FIG. 1 shows a side sectional view of a cooling device with a component to be cooled;

FIG. 2 shows a section of a cooling device in oblique view;

FIG. 3 shows an embodiment variant of a cooling device in oblique view;

FIG. 4 shows a longitudinal section through the cooling device according to FIG. 3;

FIG. 5 shows a section of a further embodiment variant of a cooling device in longitudinal section;

FIG. 6 shows an embodiment variant of a preform; and

FIG. 7 shows an embodiment variant of a tool for producing the cooling device.

### DETAILED DESCRIPTION OF PREFERRED EMBODIMENTS

By way of introduction, it should be noted that in the various embodiments described, the same parts are provided with the same reference signs or the same component designations, wherein the disclosures contained in the entire description can be transferred analogously to the same parts with the same reference signs or the same component designations. Moreover, the specifications of location, such as at the top, at the bottom, at the side, chosen in the description refer to the directly described and depicted figure and in case of a change of position, these specifications of location are to be analogously transferred to the new position.

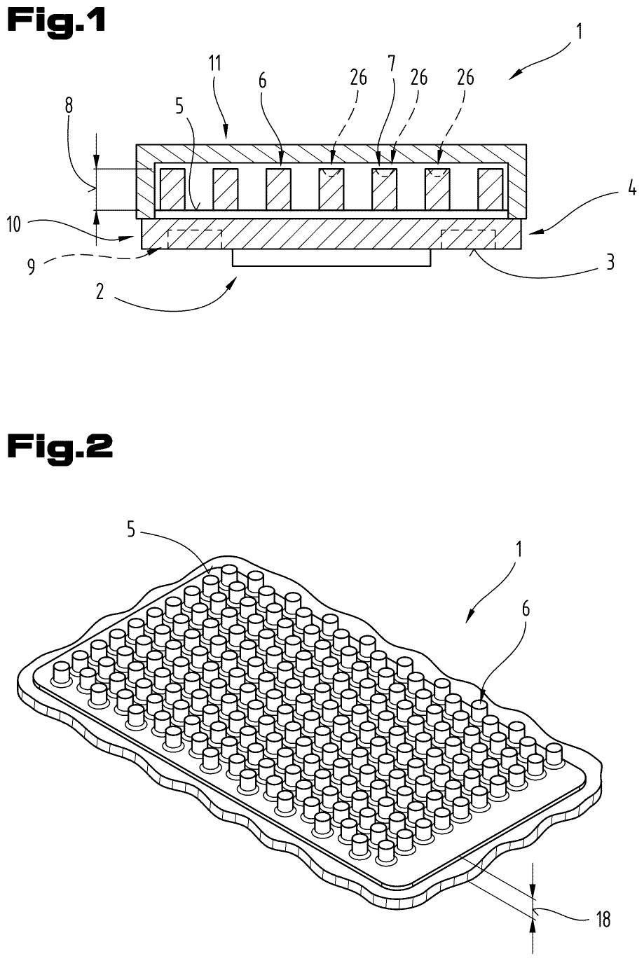

FIG. 1 shows a side view of a cooling device 1.

The cooling device 1 is used to cool a component 2 or several components 2 or an assembly. For this purpose, the cooling device 1 abuts with a rear side 3 against the at least one component 2, in particular directly, and is therefore preferably in direct contact with the component 2 for heat exchange.

The component 2 is preferably an electronic component, in particular a so-called power electronics component or high-performance electronics component or a power semiconductor or high-performance semiconductor. In particular, such components 2 or assemblies made of/with these components 2 may be designed for a power output in the range from several kW up to MW. Such components 2 are used, for example, to convert electrical energy with switching electronic components.

Typical applications include converters or frequency converters in the field of electrical drive technology, solar inverters and converters for wind turbines for feeding regeneratively generated energy into the grid or switching power supplies, generally the conversion of AC voltage into DC voltage by rectifiers, the conversion of DC voltage into AC voltage by inverters, control systems, for example in the drive technology of an electric drive in electric vehicles or hybrid vehicles, battery management systems, etc. A power electronics component may, for example, be a semiconductor, in particular a so-called power semiconductor, e.g. an insulated-gate bipolar transistor (IGBT).

Since such components 2 are known in the prior art, reference is made to this prior art in order to avoid repetition of further details.

The cooling device 1 comprises a base element 4, which has a cooling structure on a first surface 5. The cooling structure is formed by cooling elements 6, which are arranged projecting over the first surface 5 on the base element 4 and are integrally connected to it, as may also be seen in FIG. 2.

Within the scope of the invention, it is possible for several cooling devices 1 to be combined with one another per component 2 or assembly of/with at least one such component 2 to form a cooling device group in accordance with the invention. In particular, cooling devices 1 may therefore also be assembled in a modular way to form a cooling device group.

The base element 4 and the cooling elements 6 are made of or consist of a sinter material. Furthermore, the cooling elements 6 are produced by forming the base element 4 or a preform for it.

In the preferred embodiment variant, the base element 4 and the cooling elements 6 have a density of at least 98%, in particular at least 98.5%, preferably at least 99%, of the full density of the material used.

The full density refers to the density of a cooling device made from the same material using melting metallurgy, i.e. a component made from a solid material. The term “solid material” refers to a metallic material that, with the exception of imperfections, has no pores, as is usually the case with sintered components.

The cooling elements 6 are designed to be surrounded by a cooling fluid, for example water, so that the heat absorbed by the cooling device 1 is removed via this cooling fluid. Preferably, the cooling device 1 is a so-called pin fin cooling device.

The cooling elements 6 of the embodiment variant shown are cylindrical. However, they may also have a different shape, for example a truncated cone or mushroom shape, or generally one with a cross-section that expands or tapers in the direction of a cooling element head 7, for example a truncated pyramid shape.

The cross-section of the cooling elements 6 may be circular, oval, diamond-shaped, square, etc.

Furthermore, all cooling elements 6 may have the same configuration. However, it is also possible to arrange or combine cooling elements 6 with different shapes on a base element 4.

The cooling elements 6 may preferably have a height 8 above the first surface 5 of the base element 4, which is between 2 mm and 20 mm.

In the simplest embodiment of the cooling device 1, all cooling elements 6 of the cooling device 1 have the same height 8 within the tolerances. However, it is possible within the scope of the invention for some of the cooling elements 6 to have a lower height than the remaining cooling elements 6. For example, cooling elements 6 at the edges may be higher than the rest or the cooling elements 6 may have a progression of heights from lower or higher in the center of the cooling device 1 to higher or lower at the edge of the cooling device 1. Other embodiments of different heights 8 are possible within the scope of the invention.

Furthermore, it may be provided that between 300 and 1300, in particular between 300 and 1000, for example between 300 and 750, cooling elements 6 are arranged or configured per dm² of the first surface 5. In particular, this number has proven to be advantageous with regard to the production of the cooling device 1, i.e. the forming of the base element 4 to the cooling elements 6, as damage to the cooling elements 6 or incompletely formed cooling elements 6 may thus be avoided or reduced.

As may be seen in particular from FIG. 1, according to an embodiment variant of the cooling device 1, it may be provided that the rear side 3 is configured with a flat surface. However, it is also conceivable that the rear side 3 is configured with one or more depressions 9, in which a component 2 is at least partially accommodated. This enables a better connection of the component 2 to the cooling device 1. In general, the component 2 may be glued or screwed or soldered or sintered, etc., to the cooling device 1.

The at least one depression 9 may be produced at the same time as the cooling elements 6. The at least one depression 9 also makes it possible to produce cooling elements 6 whose height 8 is greater than that of the rest of the cooling elements 6.

The cooling device 1 has a bottom element 10 and a cover element 11 connected to the bottom element 10. In the embodiment variant of the cooling device 1 shown in FIG. 1, the base element 4 is arranged with the cooling elements 6 on the bottom element 10, which also forms the rear side 3, and in particular is connected to it. However, the base element 4 with the cooling elements 6 may also be arranged on the cover element 11, in particular connected to it.

However, according to embodiment variants of the invention, the base element 4 may also form the bottom element 10 and/or the cover element 11. In the “and” embodiment variant, there are two base elements 4, one of which forms the bottom element 10 and the other the cover element 11. Depending on the size of the cooling device 1, more than two base elements 4 with cooling elements 6 may also be arranged.

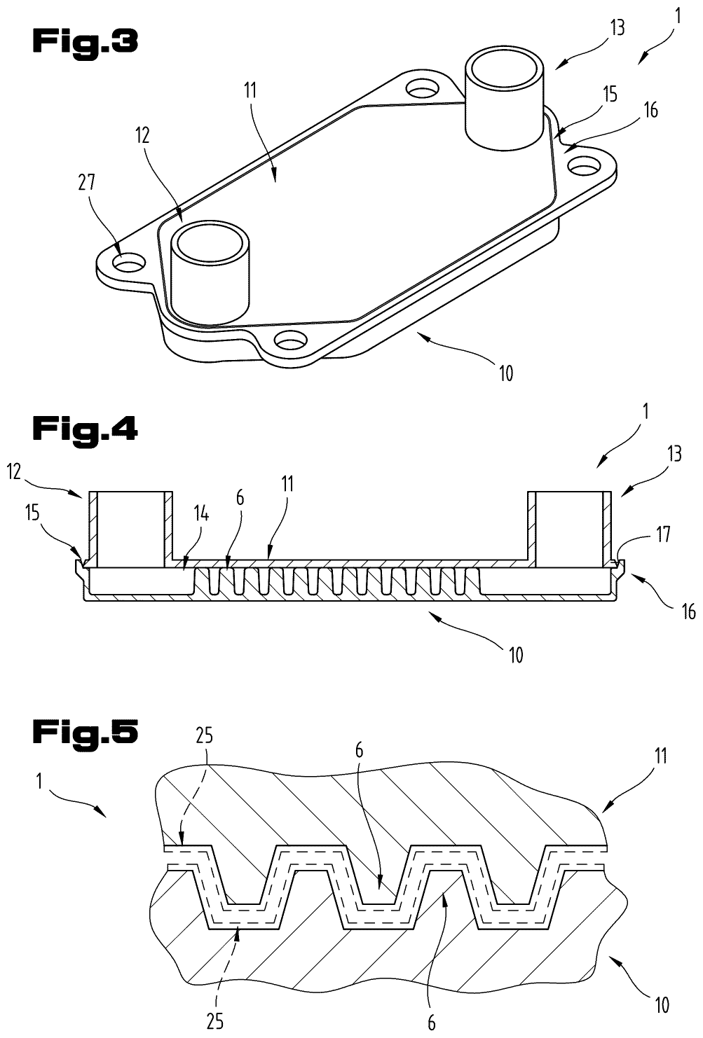

The embodiment variant “base element 4 forms the bottom element 10” is shown in FIGS. 3 and 4. The embodiment variant “a base element 4 forms the bottom element 10 and another base element 4 forms the cover element 11” is shown in part in FIG. 5.

In the preferred embodiment, the bottom element 10 or the cover element 11 or the bottom element 10 and the cover element 11 are made of or consist of a sinter material, as will be explained in more detail below with reference to the production of the base element 4 with the cooling elements 6. If the bottom element 10 or the cover element 11 is combined with a component made of a non-sinter material, this may, for example, be a punched-out component or a cut-out, in particular laser-cut, or a cast, etc., component.

Since the/a base element 4 may form the bottom element 10 and/or the cover element 11, in the preferred embodiment variant the/all cooling elements 6 are configured in one piece with the bottom element 10 or the cover element 11 or a part of the cooling elements 6 is configured in one piece with the bottom element 10 and the remaining part of the cooling elements 6 is configured in one piece with the cover element 11.

It should be noted that in the case of several base elements 4 with cooling elements 6, all base elements 4 may also have the same configuration (apart from the embodiment variant of the cooling device 1 shown in FIG. 5).

The cooling device 1 further comprises one inlet element 12 or several inlet elements 12 for feeding a liquid or gaseous cooling fluid into the cooling device 1 and one outlet element 12 or several outlet elements 12 for discharging the cooling fluid from the cooling device 1. In the embodiment variant shown in FIG. 3, the at least one inlet element 12 and the at least one outlet element 13 are arranged on the cover element 11. However, the at least one inlet element 12 and the at least one outlet element 13 may also be arranged in the bottom element 10. Furthermore, the at least one inlet element 12 may be arranged on the bottom element 10 and the at least one outlet element 13 on the cover element 11 (or vice versa).

The inlet element 10 is in flow connection with a gap 14 between the bottom element 10 and the cover element 11 via an aperture in the cover element 11 (or bottom element 10). The same applies to the outlet element 13. The cooling elements 6 are arranged in the gap 14. The inlet element 12 and the outlet element 13 also serve in particular to integrate the cooling device 1 into a cooling circuit.

The bottom element 10 is joined to the cover element 11 in a substance bonding. In principle, the substance bonding may be an adhesive connection or a welded connection. In the preferred embodiment variant, however, the substance bonding is a soldered connection, for which a corresponding solder (as filler material) is preferably used. The advantage of a soldered connection is that the cooling device 1 can also be exposed to higher temperatures (compared to an adhesive connection) and that the temperature load on the cooling elements 6 produced by forming is lower than with a welded connection.

Due to the porosity of the bottom element 10 and/or the cover element 11 caused by the sintering process, a kind of “crimping” can be achieved if necessary by the filler material penetrating into these pores and at least partially filling them. This may improve the connection strength and the fluid tightness of the substance bonding.

To configure the fluid-tight gap 14 (with the exception of the inlet element 12 and the outlet element 13), the substance bonding is preferably configured completely around the cooling structure (viewed from above) between the bottom element 10 and the cover element 11. However, it is also conceivable that a sealing element is arranged between the bottom element 10 and the cover element 11 and that in this embodiment variant the substance bonding is only configured in discrete areas between the bottom element 10 and the cover element 11.

In principle, the soldered connection may be produced using any suitable method. Preferably, however, soldering is carried out by inductive soldering or sinter soldering (in each case preferably with a solder as filler material).

With inductive soldering, only the area in which the soldered connection is configured is heated. In sinter soldering however, the filler material is introduced between the bottom element 10 and the cover element 11 and these, together with the already produced cooling structure, are placed once again in a sintering furnace.

The soldered connection may be configured as a fillet weld, for example. For this purpose, a butt joint or a T-joint or a corner joint may be formed between the bottom element 10 and the cover element 11, as is known for soldered connections.

According to a further embodiment of the cooling device 1, a joining gap 15 is configured between the bottom element 10 and the cover element 11 to receive the filler material. In the embodiment shown in FIGS. 3 and 4, this is achieved by the bottom element 10 having a collar 16 on which the cover element 11 is arranged at a distance from a side wall 17 of the collar 16, forming the (circumferential) joining gap 15. Other configurations of the joining gap are conceivable within the scope of the invention.

The joining gap 15 may, for example, have a width of between 0.05 mm and 3 mm and a depth of between 0.1 mm and 5 mm.

As may be seen from FIGS. 3 and 4, the joining gap 15 is preferably configured exclusively outside and at a distance from the cooling structure. This means that the substance bonding is also preferably configured outside the area of and at a distance from the cooling structure. The distance between the joining gap 15 and the nearest cooling element 6 may be between at least 3 mm and at least 15 mm.

The cooling elements 6 may be arranged at a distance of between 0.5 mm and 5 mm from each other. The distance is measured between two cooling elements 6 arranged directly adjacent to each other. In the embodiment variant shown in FIG. 5, the distance between the cooling elements 6 on the bottom element 10 and between the cooling elements 6 on the cover element 11 is larger, so that gaps are formed between the respective cooling elements 6, into which the cooling elements 6 of the bottom element 10 or the cover element 11 engage. In the finished cooling device 1, the distances between the cooling elements 6 may again be selected from the range mentioned above.

The base element 4 (and thus also the bottom element 10 and/or the cover element 11) may, for example, have an element height 18 (see FIG. 2) of between 3 mm and 5 mm. However, the base element 4 may also have an element height 18 of maximum 3 mm. In particular, the base element 4 may also have an element height 18 of between 1 mm and 2.5 mm. The element height 18 of the (plate-shaped) base element 4 is measured between its rear side 3 and the first surface 5. If a depression 9 is provided in the rear side 4, the element height 18 is measured next to the depression 9.

A sintering powder or a powder used in powder metallurgy, in particular a metallic powder, is used to produce the cooling device 1. Preferably, a sintering powder is used that has a correspondingly good thermal conductivity. In particular, a sintering powder based on aluminum or an aluminum alloy or based on copper or a copper alloy or a MMC (metal matrix composite) Sintering powder is used.

The cooling device 1 is produced by powder metallurgy using a powder metallurgy method and is therefore preferably a sintered component. For this purpose, a green compact is produced in a corresponding press mold (die) from a powder, which may be produced from the individual (metallic) powders by mixing, wherein the powders may be used pre-alloyed if necessary. Preferably, the green compact has a density of at least 80%, in particular between 80% and 96%, of the full density of the material.

The green compact is then dewaxed at normal temperatures and sintered in one or two stages or in several stages and then cooled, preferably to room temperature. Sintering may take place at a temperature between 500° C. and 1300° C., for example.

Since these methods and the method parameters used are also known from the prior art, reference is made to the relevant prior art in order to avoid repetition.

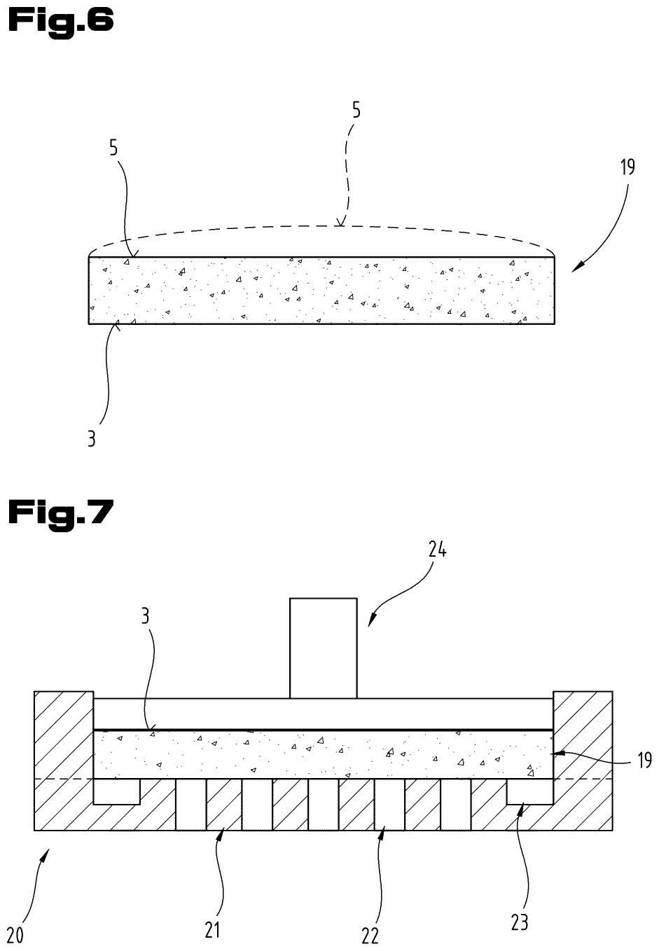

Sintering produces a preform 19 from the green compact, as shown as an example in FIG. 6. The preform 19 may be configured as a flat plate, so that the rear side 3 and the first surface 5 may run parallel to each other. A preform 19, in particular for the production of the bottom element 10, may also already have the support surfaces for the support of the cover element 11, e.g. the collar 16, to configure the gap 14 between the bottom element 10 and the cover element 11. Similarly, a preform 19, in particular for the production of the cover element 11, may have the inlet element 12 and/or the outlet element 13.

Other shapes of the first surface 5 of the preform 19 are possible with regard to improved formability of the preform 19. This means that the first pin fin projections or cooling element projections (circular, oval, elliptical, etc.) with a height of between 0.1 mm and 2.0 mm may already be preformed. In addition, structures (waves, ribs, etc.) may be deliberately introduced into the first surface 5 of the preform 19 in order to promote turbulence of the cooling fluid if necessary.

The preform 19 may subsequently be recompressed. The recompression may take place simultaneously with the forming of the preform 19 to the cooling elements 6.

The forming of the preform 19 is realized in a mold 20. For this purpose, the preform 19 is inserted into or placed against the mold 20. In the simplest case, the mold 20 for producing the cooling elements 6 is formed by a perforated plate 21. The perforated plate 21 has recesses 22, in particular apertures, into or through which some of the material of the preform 19 is pressed, forming the cooling elements 6. Depending on the shape of the collar 16, a corresponding recess 23 may be provided in the perforated plate 21.

The rest of the material of the preform 19, which is not pressed into or through the mold 20, forms the base element 4, i.e. preferably the bottom element 10 or the cover element 11. The later desired element height 18 of the base element 4 is already taken into account on the preform 19 depending on the forming to be carried out to form the cooling elements 6.

The recesses 22, 23, i.e. their cross-section, are adapted accordingly to the cross-section of the cooling elements 6 to be produced.

The mold 20 may also look different, so it does not necessarily have to be a perforated plate 21. In particular, the mold 20 may have a “pot-shaped” configuration as a die.

For forming, a punch 24 or generally a pressure tool is applied to the rear side 3 of the preform 19, which also forms the rear side 3 of the base element 4, and pressed onto the preform 19 with a predeterminable pressure. For example, forming may take place at a pressure of between 700 MPa and 1600 MPa. Furthermore, forming may take place during a time of up to 10 seconds, in particular between 0.1 seconds and 10 seconds. Furthermore, the forming preferably may take place at room temperature (20° C.), i.e. cold, or the forming may also take place after preheating the preform 20 to a temperature between 50° C. and 300° C., for example between 50° C. and 150° C., and/or in/with a mold 18 heated to a temperature between 50° C. and 300° C., for example between 50° C. and 150° C.

After the shaping, i.e. the forming of the preform 19, the cooling device 1 may be processed. For example, the cooling elements 6 may be height-calibrated or generally recompressed, for example in the free ends, for which a punch may also be used. In addition, the first surface 5 and the cooling elements 6 may be provided with a coating 25 (see FIG. 5), e.g. a corrosion-resistant coating, such as an electroplated Ni—P coating 25. The coating 25 may be applied or deposited before or after the bottom element 10 is joined to the cover element 11 in a substance bonding. Coating before the bottom element 10 is joined to the cover element 11 in a substance bonding has the advantage that the surfaces to be coated are easier to access. If subsequent removal of the coating 25 in the connection areas between the bottom element 10 and the cover element 11 prior to the configuration of the substance bonding is not desired, these areas in which the substance bonding is configured can be covered, e.g. masked, prior to the deposition or application of the coating 25. This may be avoided by depositing the coating 25 after the configuration of the substance bonding. The arrangement of, for example, the collar 16 at a distance from the cooling structure may also contribute to the fact that the coating 25 does not have to be removed in the connection areas, since the collar 16 can be arranged outside the area of the cooling structure to be coated.

The coating 25 may, for example, have a layer thickness of between 1 μm and 500 μm.

The preform 19 may be formed in one or more stages, so that the cooling elements 6 and the base element 4 or the bottom element 10 or the cover element 11 can be formed in one or more stages.

According to an embodiment variant, it is also conceivable for at least some of the cooling elements 6 to be connected to both the bottom element 10 and the cover element 11. For example, the bottom element 10 or the cover element 11 may be heated from the outside in the abutment area of the cooling element 6 to be connected, e.g. with a laser. The area to be heated can be no larger than the cross-section of the cooling element 6 in the cooling element head 7. For example, a circular or annular area of the substance bonding may be configured between the cooling element 6 and the bottom element 10 or the cover element 11.

In order to be able to provide an additional material for this substance bonding of the cooling element 6 to the bottom element 10 or the cover element 11, according to one embodiment variant it may be provided that joining recesses 26 (joining depressions) are configured in the cooling element heads 7 of the cooling elements 6, which are connected both to the bottom element 10 and to the cover element 11, as indicated by stroke-dotted lines in FIG. 1. The joining recesses 26 may be formed, for example, during the forming of the preform 19 to the cooling elements 6, for example by the mold 20 for configuring the cooling elements 6 with joining recess 26 not having an opening, but only a depression with a corresponding contour of the bottom of the depression for forming the joining recess 26. A filler material, e.g. a solder, may be arranged in the joining recesses 26. This may be liquefied by laser or induction, for example. Sinter soldering of the cooling element 6 is also possible.

In addition to configuring the substance bonding between the bottom element 10 and the cover element 11, a form-fit connection may also be provided by configuring corresponding form-fit elements (e.g. in the form of a tongue-and-groove-joint) in the bottom element 10 and/or in the cover element 11.

It may also be provided that the inlet element 12 and/or the connection element 13 are arranged in a side wall of the cooling device 1.

As may be seen from FIG. 3, the bottom element 10 may be produced with openings 27, via which the cooling device can be connected to the component 2 to be cooled, for example by screwing it together.

The shape of the cooling device 1 shown in the figure is only intended to explain the invention. The cooling device 1 may also have a different shape.

The exemplary embodiments show possible embodiment variants, wherein it should be noted at this point that combinations of the individual embodiment variants with one another are also possible.

Finally, for the sake of order, it should be noted that for a better understanding of the structure of the cooling device 1, this is not necessarily shown to scale.

Although only a few embodiments of the present invention have been shown and described, it is to be understood that many changes and modifications may be made thereunto without departing from the spirit and scope of the invention.

### REFERENCE SIGNS LIST

1 cooling device
2 component
3 rear side
4 base member
5 surface
6 cooling element
7 cooling element head
8 height
9 depression
10 bottom element
11 cover element
12 inlet element
13 outlet element
14 gap
15 joining gap
16 collar
17 side wall
18 element height
19 preform
20 mold
21 perforated plate
22 recess
23 recess
24 punch
25 coating
26 joining recess
27 aperture

What is claimed is:

1. A method for producing a cooling device (1) with a bottom element (10) and a cover element (11) connected thereto, wherein a cooling structure with cooling elements (6) is arranged between the bottom element (10) and the cover element (11), comprising the steps of providing a material and configuring a cooling structure from the material, wherein a sintering powder is used as the material, from which at least one green compact is produced by pressing, wherein the green compact is sintered to form a preform (19), and the cooling structure in the form of cooling elements (6) is produced from the preform (19) by forming, for which purpose a part of the preform (19) is pressed through a mold (20), and wherein, after arrangement of the cooling structure between the bottom element (10) and the cover element (11), the bottom element (10) is joined to the cover element (11) in a substance bonding.

2. The method according to claim 1, wherein the bottom element (10) is produced from at least one preform (19) and/or the cover element (11) is produced from at least one preform (19).

3. The method according to claim 2, wherein cooling elements (6) of the cooling structure are configured in one piece with the bottom element (10) and/or wherein cooling elements (6) of the cooling structure are configured in one piece with the cover element (11).

4. The method according to claim 1, wherein the substance bonding is configured outside the area of the cooling structure.

5. The method according to claim 4, wherein a joining gap (15) is configured in the bottom element (10) or in the cover element (11).

6. The method according to claim 1, wherein the substance bonding is configured as a soldered connection.

7. The method according to claim 6, wherein the soldered connection is produced by inductive soldering or sinter soldering.

8. The method according to claim 1, wherein at least some of the cooling elements (6) are connected both to the bottom element (10) and to the cover element (11).

9. The method according to claim 8, wherein joining recesses (26) are configured in cooling element heads (7) of the cooling elements (6), which are connected both to the bottom element (10) and to the cover element (11).

10. The method according to claim 1, wherein a coating (25) is applied on the cooling structure.

11. The method according to claim 10, wherein the coating (25) is carried out before or after the joining of the bottom element (10) to the cover element (11) in a substance bonding.

12. A cooling device (1) comprising a bottom element (10) and a cover element (11) connected thereto, wherein a cooling structure with cooling elements (6) is arranged between the bottom element (10) and the cover element (11), wherein the cooling structure is produced from a formed sinter material and wherein the bottom element (10) is joined to the cover element (11) in a substance bonding.

13. The cooling device (1) according to claim 12, wherein cooling elements (6) of the cooling structure are configured in one piece with the bottom element (10) and/or cooling elements (6) of the cooling structure are configured in one piece with the cover element (11).

14. The cooling device (1) according to claim 12, wherein the substance bonding between the bottom element (10) and the cover element (11) is a soldered connection.

15. The cooling device (1) according to claim 14, wherein the soldered connection is configured in a joining gap (15), the joining gap (15) being configured outside the cooling structure.
